(19) United States
(12) Patent Application Publication
(10) Pub. No.: US 2024/0304643 A1
(43) Pub. Date: Sep. 12, 2024

(54) STRUCTURE AND SOLID-STATE IMAGING DEVICE

(71) Applicant: Mitsubishi Chemical Corporation, Tokyo (JP)

(72) Inventors: Shigeki HATTORI, Tokyo (JP); Shuuhei NAKAJIMA, Tokyo (JP)

(73) Assignee: Mitsubishi Chemical Corporation, Tokyo (JP)

(21) Appl. No.: 18/669,994

(22) Filed: May 21, 2024

Related U.S. Application Data
(63) Continuation of application No. PCT/JP2022/043338, filed on Nov. 24, 2022.

(30) Foreign Application Priority Data
Nov. 25, 2021 (JP) 2021-191260

(51) Int. Cl. H01L 27/146

(52) U.S. Cl. CPC H01L 27/14621; H01L 27/14649; H01L 27/14645

(57) ABSTRACT

A structure and a solid-state imaging device, each of which enables high-level imaging by infrared rays. The structure is provided with a plurality of color filters positioned on a support, in which the color filters include a first infrared color filter and a second infrared color filter. When a near-infrared region is divided into two parts, a short wavelength side is defined as a specific wavelength band 1, and a long wavelength side is defined as a specific wavelength band 2, the first infrared color filter shields light in a visible region, transmits at least a part of light in the specific wavelength band 1, and shields light in the specific wavelength band 2, and the second infrared color filter shields light in the visible region, shields light in the specific wavelength band 1, and transmits at least a part of light in the specific wavelength band 2.

This application is a continuation application of International Application No. PCT/JP2022/043338, filed on Nov. 24, 2022, which claims the benefit of priority of the prior Japanese Patent Application No. 2021-191260, filed in Japan on Nov. 25, 2021, the entire contents of which are incorporated herein by reference.

### BACKGROUND OF THE INVENTION

### Field of the Invention

The present invention relates to a structure and a solid-state imaging device.

### Description of Related Art

In general, a solid-state imaging device is known for an application thereof for obtaining a digital camera image or a video image by spectrally splitting visible light into, for example, three colors of red (R), green (G), and blue (B), and capturing the image as a color image. In addition to this application, the solid-state imaging device can also be used for measurement as in a light sensor and the like. Therefore, in recent years, it has begun to be utilized for distance measurement or three-dimensional measurement.

In the distance measurement or the three-dimensional measurement, infrared rays which have a wavelength longer than that of visible light and are less likely to be scattered are considered to be useful. Since the infrared rays are not visible to humans or animals, they enable measurement at night as well as natural measurement. In an infrared sensor using such infrared rays, an infrared transmitting filter is essential.

In addition, in recent years, healthcare devices that measure a heart rate and a blood oxygen concentration, using infrared rays, have been actively developed. Therefore, there is a demand for a solid-state imaging device that enables high-level imaging to be performed by infrared rays in order to monitor biological information in more detail.

In the related art, an infrared transmitting filter has been proposed as an independent light transmitting filter separated from visible light. Patent Document 1 discloses a solid-state imaging device in which a film formed of a composition including a coloring material is used as an infrared transmitting filter.

### DOCUMENTS OF RELATED ART

### Patent Document

Patent Document 1: PCT International Publication No. WO 2019/150833

### SUMMARY OF THE INVENTION

However, the solid-state imaging device disclosed in Patent Document 1 is only provided with color filters of three colors (R, G, and B) of visible light and an infrared transmitting filter of only one color in an infrared region at wavelengths of 700 nm or more, but did not enable high-level imaging to be performed by infrared rays.

The present invention has been made in view of such circumstances and an object of the present invention is to provide a structure and a solid-state imaging device, each of which enables high-level imaging to be performed by infrared rays.

### Means for Solving Problems

The present invention includes the following configurations.

[1] A structure comprising:
a plurality of color filters positioned on a support,
wherein the color filters include a first infrared color filter and a second infrared color filter, and
when a near-infrared region is divided into two parts, a short wavelength side is defined as a specific wavelength band 1, and a long wavelength side is defined as a specific wavelength band 2,
the first infrared color filter shields light in a visible region, transmits at least a part of light in the specific wavelength band 1, and shields light in the specific wavelength band 2, and
the second infrared color filter shields light in the visible region, shields light in the specific wavelength band 1, and transmits at least a part of light in the specific wavelength band 2.

[2] The structure according to [1],
wherein a wavelength range of 700 to 900 nm is divided into two parts, a short wavelength side is defined as the specific wavelength band 1, and a long wavelength side is defined as the specific wavelength band 2.

[3] The structure according to [2],
wherein the specific wavelength band 1 is in a wavelength range of 700 to 800 nm and the specific wavelength band 2 is in a wavelength range of 800 to 900 nm.

[4] The structure according to [1],
wherein the color filters include a plurality of infrared shielding and visible transmitting filters that shield light in the near-infrared region and transmit at least a part of light in the visible region.

[5] The structure according to [1],
wherein the first infrared color filter has an average transmittance in the specific wavelength band 1 of 30% or more and an average transmittance in the specific wavelength band 2 of 0.1% or less.

[6] The structure according to [1] or [5],
wherein the second infrared color filter has an average transmittance in the specific wavelength band 1 of 0.1% or less and an average transmittance in the specific wavelength band 2 of 30% or more.

[7] The structure according to [3],
wherein the first infrared color filter has an average transmittance in a wavelength range of 700 to 800 nm of 30% or more and an average transmittance in a wavelength range of 800 to 900 nm of 0.1% or less.

[8] The structure according to [3] or [7],
wherein the second infrared color filter has an average transmittance in a wavelength range of 700 to 800 nm of 0.1% or less and an average transmittance in a wavelength range of 800 to 900 nm of 30% or more.

[9] The structure according to any one of [1] to [8],
wherein the first infrared color filter and the second infrared color filter are films obtained from a photosensitive resist containing a colorant.

[10] The structure according to any one of [1] to [9], wherein the color filters have a maximum transmittance of 35% or more in a wavelength range of 400 to 900 nm.

[11] The structure according to any one of [1] to [10],
wherein the color filters constitute a color filter array disposed in a planar shape.

[12] The structure according to [4],
wherein the infrared shielding and visible transmitting filters include a green color filter, and
a proportion of an area occupied by the green color filter with respect to an area occupied by the infrared shielding and visible transmitting filters is the highest.

[13] The structure according to [4],
wherein the infrared shielding and visible transmitting filters include a blue color filter that transmits light at a wavelength of 400 to 500 nm, a green color filter that transmits light at a wavelength of 500 to 600 nm, and a red color filter that transmits light at a wavelength of 600 to 700 nm.

[14] The structure according to [4],
wherein the infrared shielding and visible transmitting filters have an average transmittance in a wavelength range of 700 to 900 nm of 0.1 or less.

[15] A solid-state imaging device comprising:
the structure according to any one of [1] to [14].

[16] The solid-state imaging device according to [15], further comprising:
an infrared cut filter that shields light at a wavelength of more than 900 nm;
a photoelectric conversion device having a sensitivity to visible light and light at a wavelength of 700 to 900 nm;
a readout circuit that reads out an electrical signal photoelectrically converted by the photoelectric conversion device; and
a signal processing section that performs signal processing on the electrical signal read out by the readout circuit.

[17] The solid-state imaging device according to [16],
wherein the infrared cut filter is a laminated film in which a plurality of films including two or more kinds of substances with different optical refractive indices are laminated.

[18] The solid-state imaging device according to or [17],
wherein the photoelectric conversion device is a photodiode using silicon.

### Effects of the Invention

Using the structure and the solid-state imaging device of the present invention, high-level imaging can be performed by infrared rays.

### BRIEF DESCRIPTION OF THE DRAWINGS

FIG. 1 is a cross-sectional view schematically showing a configuration of an embodiment of a solid-state imaging device of the present invention.

FIG. 2 is a perspective view schematically showing a configuration of a main part of an embodiment of the solid-state imaging device of the present invention.

FIG. 3 is a plan view showing an example of an arrangement of color filters constituting an embodiment of the solid-state imaging device of the present invention.

FIG. 4 is a spectroscopic spectrum view in color filters of Examples.

### DETAILED DESCRIPTION OF THE INVENTION

Hereinafter, embodiments of the present invention will be described in detail. Furthermore, the present invention is not limited to the following description, and those other than the following examples can be appropriately modified and implemented as long as a gist of the present invention is not impaired.

The definitions of the following terms used in the present invention shall apply in the present specification and the range of claims.

A “color filter” is an optical filter that acts on light in a visible region and an infrared region among filters for electromagnetic waves, and is intended to exhibit characteristics with respect to colors (differences in wavelength).

The “visible region” means a wavelength band in a wavelength range of 400 to 700 nm.

The “infrared region” means a wavelength band in a wavelength range of 700 to 900 nm.

A term “to” between values is used in the sense that the numerical values described before and after the term are each included as a lower limit value and an upper limit value.

### First Embodiment

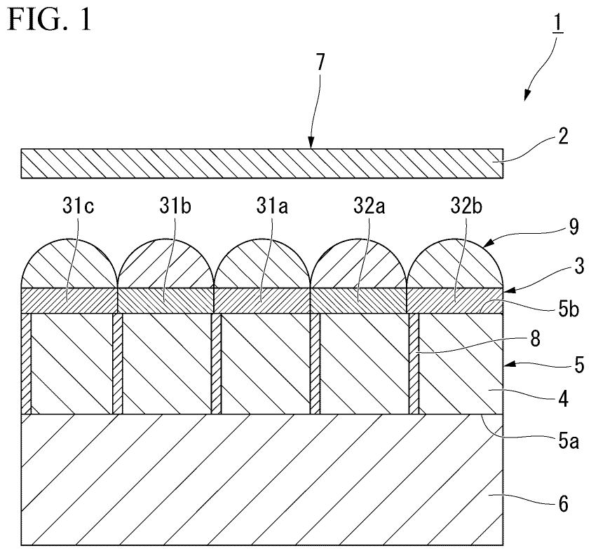

First, a configuration of an embodiment of the solid-state imaging device of the present invention will be described. FIG. 1 is a cross-sectional view schematically showing a configuration of a solid-state imaging device 1 (hereinafter also referred to as a first embodiment) which is an embodiment of the present invention.

As shown in FIG. 1, the solid-state imaging device 1 which is the first embodiment is roughly configured to be provided with an infrared cut filter 2, a plurality of color filters 3, a photoelectric conversion device 4, a readout circuit (not shown), and a signal processing section (not shown)

The solid-state imaging device 1 is a rear surface irradiation-type solid-state imaging device in which a wiring region 6 is formed on one surface (front surface) 5a of a semiconductor substrate 5 such as a silicon substrate, and a light receiving region 7 is formed on the other surface (rear surface) 5b. Hereinafter, the rear surface irradiation-type solid-state imaging device 1 will be described as an example.

The wiring region 6 is a region provided with a wiring for transmitting a signal. The wiring region 6 includes a wiring layer (not shown) that transmits a signal to the photoelectric conversion device 4 formed on the semiconductor substrate 5, and an insulating layer (not shown) that insulates the wiring layer.

The semiconductor substrate 5 is compartmentalized into a plurality of regions by a partition wall 8 and the photoelectric conversion device 4 is formed in each region. The color filters 3 are each provided on the rear surface 5b of the semiconductor substrate 5 on which the photoelectric conversion device 4 has been formed, and each constitute a pixel. That is, a plurality of pixels are arranged in the light receiving region 7.

Moreover, in the light receiving region 7, microlenses 9 serving as light condensing means are laminated on a plurality of pixels (on a plurality of color filters 3). In addition, the infrared cut filter 2 is disposed on a side of the microlenses 9 opposite to the color filters 3 through an air layer.

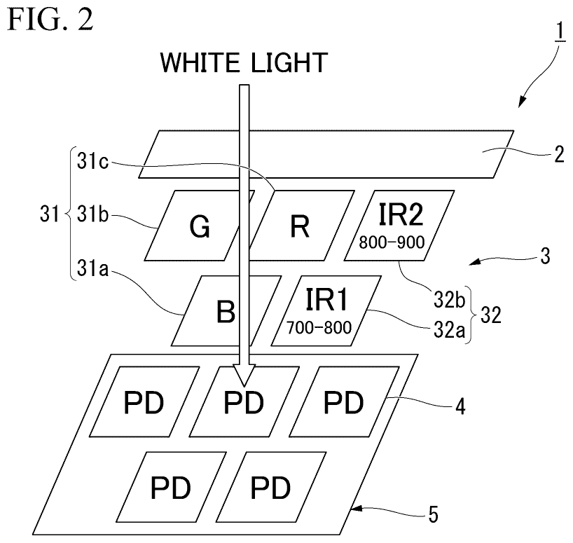

As shown in FIG. 2, the solid-state imaging device 1 of the first embodiment includes a plurality of color filters 3 positioned on the semiconductor substrate 5 which is a support.

The color filters 3 include a plurality of infrared shielding and visible transmitting filters 31 and visible shielding and infrared transmitting filters 32.

The infrared shielding and visible transmitting filters 31 shield light in an infrared region (wavelength of 700 to 900 nm) and transmit light in a specific wavelength band of a visible region (wavelength of 400 to 700 nm). In the first embodiment, the infrared shielding and visible transmitting filters 31 include a blue (B) color filter 31a that transmits light at a wavelength of 400 to 500 nm (meaning that it transmits at least a part of light in this wavelength region, which applies hereinafter), a green (G) color filter 31b that transmits light at a wavelength of 500 to 600 nm, and a red (R) color filter 31c that transmits light at a wavelength of 600 to 700 nm (a combination of these color filters are also referred to as “primary color filters”).

Here, shielding light in an infrared region (wavelength of 700 to 900 nm) means that a transmittance for light in the infrared region is small, and specifically that an average transmittance in the infrared region is preferably 0.1% or less, and more preferably 0.01% or less. The lower limit is not particularly limited, and is preferably 0%.

In addition, transmitting light in a specific wavelength band of a visible region (wavelength of 400 to 700 nm) means that a transmittance for light in a specific wavelength band of the visible region is large, and specifically that a maximum transmittance in a specific wavelength band of the visible region is preferably 35% or more, and more preferably 55% or more. The upper limit is not particularly limited, and is preferably 100%.

When light in a specific wavelength band of the visible region (wavelength of 400 to 700 nm) is transmitted, the average transmittance in the specific wavelength band of the visible region is preferably 30% or more, more preferably 50% or more, and still more preferably 70% or more. The upper limit is not particularly limited, and is preferably 100%.

In the first embodiment, by providing a plurality of infrared shielding and visible transmitting filters, when an infrared signal is received for biological monitoring and the like, the received infrared signal does not enter the photodiode (PD) for receiving visible light, and R, G, and B monochromatic signals can be captured correctly. When R, G, and B visible light transmitting filters that do not shield infrared rays are provided, the incident infrared signal also enters the R, G, and B visible light transmitting filters, and the received infrared signal enters photodiodes below all the transmitting filters. Therefore, the signals are output from all the photodiodes, causing images to be whitened.

As the blue color filter 31a, the green color filter 31b, and the red color filter 31c, color filters having a known configuration in the related art, which are provided with a function of shielding all light in an infrared region (700 to 900 nm), can be used. Specific examples of the color filter include a color filter obtained by adding a near-infrared absorbing colorant to the color filter having the configuration disclosed in PCT International Publication No. WO2015/080217.

Examples of the near-infrared absorbing colorant include organic materials such as a cyanine-based dye, a merocyanine-based dye, a squarylium-based dye, a phthalocyanine-based dye, a diimmonium-based dye, and a diketopyrrolopyrrole-based dye, and inorganic materials such as lanthanum hexaborate, cesium-doped tungsten oxide, and a copper phosphate compound.

It is desirable that the near-infrared absorbing colorants mentioned above have optical characteristics that do not decrease a visible transmittance in the wavelength range of 400 to 700 nm as much as possible. In addition, it is necessary to set the addition amount to a necessary minimum so that the visible transmittance may not be decreased as much as possible. It should be noted that when the addition amount is too small, the near-infrared rays in the wavelength range of 700 to 900 nm cannot be shielded, and thus, the adjustment is required. The addition amount depends on an absorption and attenuation coefficient of the near-infrared absorbing colorant, but it is desirable for the concentration to be 0.1% to 20% by mass with respect to the color filters, for example.

The visible shielding and infrared transmitting filters 32 shield light in the visible region (wavelength of 400 to 700 nm) and transmit light in a specific wavelength band of the infrared region (wavelength of 700 to 900 nm). In the first embodiment, the visible shielding and infrared transmitting filters 32 include a first infrared color filter 32a that transmits light in the wavelength range of 700 to 800 nm and shields light in a wavelength range of 800 to 900 nm, and a second infrared color filter 32b that transmits light in the wavelength range of 800 to 900 nm and shields light in the wavelength range of 700 to 800 nm.

Here, shielding light in a visible region (wavelength of 400 to 700 nm) means that a light transmittance in the visible region is small, and specifically that an average transmittance in the visible region is preferably 0.1% or less, and more preferably 0.01% or less. The lower limit is not particularly limited, and is preferably 0%.

In addition, transmitting light in the wavelength range of 700 to 800 nm or the wavelength range of 800 to 900 nm means that the transmittance in the wavelength range is large, and specifically that the maximum transmittance in a specific wavelength band of the infrared region is preferably 35% or more, and more preferably 55% or more. The upper limit is not particularly limited, and is preferably 100%.

When the light in the wavelength range of 700 to 800 nm or the wavelength range of 800 to 900 nm is transmitted, the average transmittance in the wavelength range is preferably 30% or more, more preferably 50% or more, and still more preferably 70% or more. The upper limit is not particularly limited, and is preferably 100%.

In addition, shielding the light in the wavelength range of 700 to 800 nm or the wavelength range of 800 to 900 nm means that the transmittance in the wavelength ranges is small, and specifically that the average transmittance in the wavelength range is preferably 0.1% or less, and more preferably 0.01% or less. The lower limit is not particularly limited, and is preferably 0%.

In the first embodiment, by providing two visible shielding and infrared transmitting filters, only infrared rays are transmitted even when visible light and infrared rays of R, G, and B are incident at the same time. Therefore, the infrared signals intended to be captured are not inhibited by visible light, making it possible to receive the light correctly.

The first infrared color filter 32a is not particularly limited as long as it transmits light in the wavelength range of 700 to 800 nm and shields light in the wavelength range of 800 to 900 nm. Examples of the first infrared color filter 32a include a film obtained from a photosensitive resist containing a colorant, or a film patterned by a vapor deposition and sputtering method using an inorganic material. From the viewpoint of production cost, a film obtained from a photosensitive resist containing a colorant is preferable.

Examples of the colorant include a cyanine-based dye, a merocyanine-based dye, a squarylium-based dye, a phthalocyanine-based dye, a diimmonium-based dye, and a diketopyrrolopyrrole-based dye.

Examples of the inorganic material include lanthanum hexaborate, cesium-doped tungsten oxide, and a copper phosphate compound.

The second infrared color filter 32b is not particularly limited as long as it transmits light in the wavelength range of 800 to 900 nm and shields light in the wavelength range of 700 to 800 nm. Examples of the second infrared color filter 32b include a film obtained from a photosensitive resist containing a colorant, or a film patterned by a vapor deposition and sputtering method using an inorganic material. From the viewpoint of production cost, a film obtained from a photosensitive resist containing a colorant is preferable.

Examples of the colorant include a cyanine-based dye, a merocyanine-based dye, a squarylium-based dye, a phthalocyanine-based dye, a diimmonium-based dye, and a diketopyrrolopyrrole-based dye.

Examples of the inorganic material include lanthanum hexaborate, cesium-doped tungsten oxide, and a copper phosphate compound.

As shown in FIGS. 1 and 2, in the solid-state imaging device 1 of the first embodiment, a plurality of color filters 3 are arranged in a planar shape to form a color filter array. The color filter array is disposed to be perpendicular to light incident into a pixel region which serves as the light receiving region 7 of the solid-state imaging device 1.

In the color filter array, color filters of a total of five colors including three colors of the RGB primary color filters 31a to 31c and two colors of the first and second infrared color filters 32a and 32b are arranged.

The arrangement of the color filters of five colors in the color filter array is not particularly limited, and may be a striped arrangement or a mosaic arrangement.

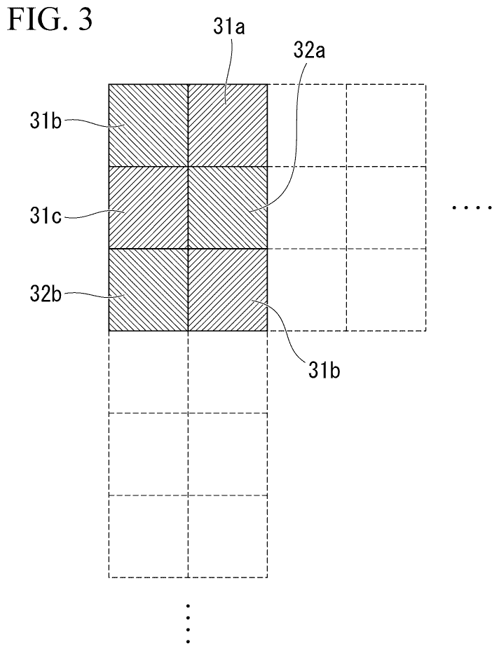

In addition, as shown in FIG. 3, an arrangement in which a general “Bayer method” is expanded to five colors may be used as the arrangement of three colors of RGB.

In the color filter array including color filters of five colors, which constitutes the solid-state imaging device 1 of the first embodiment, a ratio of occupied areas between the infrared shielding and visible transmitting filters 31 and the visible shielding and infrared transmitting filters 32 is not particularly limited, and the area ratio can be appropriately selected according to an application of the solid-state imaging device 1.

In addition, in the color filter array, for the purpose of improving a resolution, when the total occupied area of the infrared shielding and visible transmitting filters 31 is taken as 100%, the proportion of the occupied area of the green color filter 31b is preferably the highest. Specifically, when the primary color filters 31a to 31c of RGB are included as the infrared shielding and visible transmitting filters 31, the proportion of the occupied area of the green color filter 31b is preferably 33% or more. Since a human vision has poor sensitivity to a green color, the proportion that is the lower limit value or more can compensate for the low sensitivity. Thus, the proportion is desirable. The upper limit is preferably 50% or less and, and the proportion that is the upper limit value or less enables a proportion of the green color to be not too large and makes a tone of the green color to be not too strong. Thus, such a proportion is desirable.

In the solid-state imaging device 1 of the first embodiment, any of the color filters of five colors have a maximum transmittance in the wavelength range of 400 to 900 nm of preferably 35% or more, more preferably 45% or more, and still more preferably 55% or more. When the maximum transmittance of each color filter in the wavelength range of 400 to 900 nm is the lower limit value or more, there is a tendency that the photoelectric conversion device 4 can reliably receive light. The upper limit is not particularly limited, and is preferably 100%.

As shown in FIG. 1 and FIG. 2, the photoelectric conversion device 4 outputs a current in accordance with irradiated (incident) light. As the photoelectric conversion device 4, a photodiode using silicon (Si), indium-gallium-arsenide (InGaAs), or an organic material can be applied, and a photodiode using silicon is desirable from the viewpoint of production cost.

The photoelectric conversion device 4 has a sensitivity to at least one light in the visible region (wavelength of 400 to 700 nm) and the infrared region (wavelength of 700 to 900 nm). By using appropriate combinations of the color filters 3 and the photoelectric conversion device 4, a current can be output in accordance with irradiated (incident) light.

In particular, it is required for the photoelectric conversion device 4 used in combination with the visible shielding and infrared transmitting filters 32 to have a sensitivity to light at a wavelength of 700 to 900 nm.

In addition, it is preferable that the photoelectric conversion device 4 has a sensitivity to light in both the visible region and the infrared region. According to such a photoelectric conversion device 4, even when being used in combination with any of the color filters of five colors, a current can be output in accordance with irradiated (incident) light. Examples of the photoelectric conversion device 4 having a sensitivity to light in both the visible region and the infrared region include the photodiode described in “Improvement of Infrared Sensitivity of Rear surface Irradiation-Type CMOS Image Sensor Using PSD Structure”, ITE Technical Report Vol. 42, No. 10.

As shown in FIG. 1 and FIG. 2, the infrared cut filter 2 is provided over the entire surface of the light receiving region 7 of the solid-state imaging device 1. The infrared cut filter 2 is not particularly limited as long as it transmits light at a wavelength of 900 nm or less and shields light at a wavelength of more than 900 nm. Examples of such an infrared cut filter 2 include a laminated film in which a plurality of films including two or more kinds of substances having different optical refractive indices are laminated.

As the infrared cut filter 2, specifically, SI0900 (long-wavelength cut filter IR 900 nm) manufactured by Asahi Spectra Co., Ltd., and the like can be used.

The readout circuit reads out the current photoelectrically converted by the photoelectric conversion device 4 as an electrical signal. Specifically, the wiring region 6 formed on the surface 5a of the semiconductor substrate 5 functions as a readout circuit.

The signal processing section (not shown) performs signal processing on the electrical signals read out by the readout circuit.

Next, a method for producing the solid-state imaging device 1 of the first embodiment will be described.

The solid-state imaging device 1 of the first embodiment first forms a wiring region 6 on a support substrate (not shown) and then forms a photodiode using silicon on which a partition wall 8 has been formed, and the photodiode is used as the photoelectric conversion device 4. In such a rear surface irradiation-type image sensor, it is considered that by making a silicon layer of a light receiving sensor section into a thin layer to obtain a high sensitivity. As a production method therefor, a method in which the photoelectric conversion device 4 is formed and then the silicon substrate is etched or polished is considered. Specific examples of the method include the methods disclosed in Japanese Unexamined Patent Application, First Publication No. H6-77461, Japanese Unexamined Patent Application, First Publication No. H6-283702, and the like.

Next, color filters 3 are formed on an etched or polished rear surface 5b of a semiconductor substrate 5 on which the photoelectric conversion device 4 has been formed, in accordance with the regions compartmentalized by the partition wall 8. The color filters 3 are formed by sequentially patterning color filters 3 of five colors using a resist method or a vapor deposition and sputtering method which is a known technique.

Next, a microlens 9 is formed on each of the color filters 3 and the infrared cut filter 2 is then laminated.

As described above, the solid-state imaging device 1 of the first embodiment can be produced.

Next, a case where the solid-state imaging device 1 of the first embodiment is irradiated with white light will be described.

First, as shown in FIG. 1 and FIG. 2, in the irradiated white light, light at a wavelength of more than 900 nm is shielded by the infrared cut filter 2 and then condensed by each microlens 9.

Next, the light condensed by the microlens 9 is incident on the color filters 3 of five colors (that is, the primary color filters 31a to 31c of RGB, and the first and second infrared color filters 32a and 32b). Light in a specific wavelength band in the light incident on each of the color filters 3 is transmitted.

Next, the light transmitted through each of the color filters 3 is incident on the photoelectric conversion device 4. Then, each photoelectric conversion device 4 outputs a current in accordance with the incident light.

Next, the current output from the photoelectric conversion device 4 is read out as an electrical signal by a readout circuit, and subjected to signal processing by a signal processing section.

As described above, according to the solid-state imaging device 1 of the first embodiment, the visible shielding and infrared transmitting filters 32 of two colors (32a and 32b) are provided, in addition to the infrared shielding and visible transmitting filters 31 (31a to 31c) of three colors of RGB. Therefore, an infrared spectroscopic image having a wavelength of 800 nm as a middle point in the infrared region at wavelengths of 700 to 900 nm can be obtained at the same time as the color image.

Therefore, the solid-state imaging device 1 of the first embodiment is useful as an infrared sensor, and can be preferably used for applications such as iris authentication, distance measurement, a proximity sensor, a gesture sensor, a motion sensor, a time-of-flight (TOF) sensor, a vein sensor, blood vessel visualization, blood oxygen concentration measurement, sebum amount measurement, fluorescent labeling, and surveillance cameras.

In addition, the solid-state imaging device 1 of the first embodiment can be used by being incorporated into an image display device (for example, a liquid crystal display device and an organic electroluminescence (organic EL) display device), and the like.

### Other Embodiments

Moreover, the technical scope of the present invention is not limited to the embodiments and includes designs and the like within a range not departing from the gist of the present invention. For example, in the above-described solid-state imaging device 1 of the first embodiment, a configuration provided with the infrared cut filter 2 has been described as an example, but the present invention is not limited thereto. For example, when each of the color filters 3 shields light at a wavelength of 900 nm or more, the configuration may be such that the infrared cut filter 2 is omitted.

In addition, in the above-described solid-state imaging device 1 of the first embodiment, a configuration in which the infrared shielding and visible transmitting filters 31 include primary color filters 31a to 31c of three colors of RGB is described as an example, but the present invention is not limited thereto. For example, a configuration in which the infrared shielding and visible transmitting filters 31 are color filters that transmit three or more colors, for example, four colors of CMYG, “cyan”, “magenta”, “yellow”, and “green” may be available.

In addition, in the above-described solid-state imaging device 1 of the first embodiment, a configuration in which the visible shielding and infrared transmitting filters 32 include two colors of the first and second infrared color filters 32a and 32b is described as an example, but the present invention is not limited thereto. For example, a configuration in which three or more visible shielding and infrared transmitting filters 32 that spectrally split an infrared region in wavelengths of 700 to 900 nm into three or more colors are included may be available.

In addition, in the above-described solid-state imaging device 1 of the first embodiment, an aspect in which a wavelength branching point in the infrared region that is shielded by the first and second infrared color filters 32a and 32b is 800 nm, but this branching point only needs to be within the infrared region; and when the short wavelength side from 700 nm to the branching point is defined as a specific wavelength band 1 and the long wavelength side from the branching point to 900 nm is defined as a specific wavelength band 2, the first infrared color filter shields in the visible region and the specific wavelength band 2, and transmits in the specific wavelength band 1, and the second infrared color filter shields in the visible region and the specific wavelength band 1, and transmits in the specific wavelength band 2 may be available.

In addition, within a range not departing from the gist of the present invention, the constituent elements in the above-described embodiments can be appropriately replaced with known constituent elements, and the above-described modification examples may be appropriately combined.

### Examples

Hereinafter, the effects of the present invention will be specifically described. Furthermore, the present invention is not limited to the following verification tests.

### Green Colorant A

A green colorant A which is a phthalocyanine compound A having a chemical structure represented by General Formula (11), which had been synthesized based on Example 30 of Japanese Unexamined Patent Application, First Publication No. H05-345861, was used.

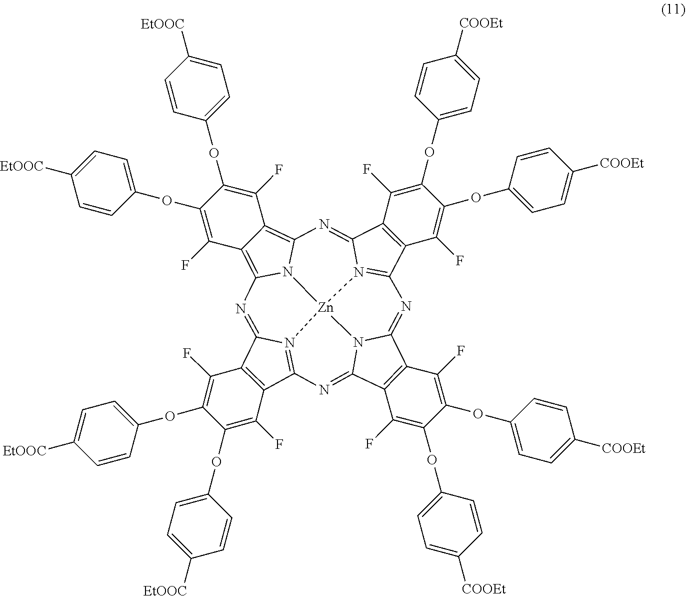

### Blue Colorant A

A blue colorant A having a chemical structure represented by General Formula (12), which had been synthesized based on PCT International Publication No. WO2015/080217, was used.

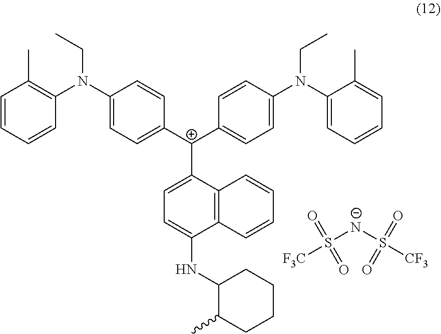

### Red Colorant A

A red colorant A having a chemical structure represented by General Formula (13), which had been synthesized based on Japanese Patent No. 6846739, was used.

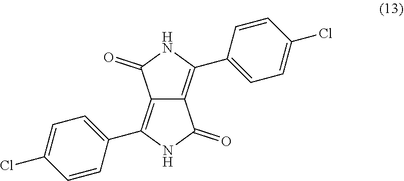

### Black Colorant A

Irgaphor (registered trademark) Black S 0100 CF (having a chemical structure represented by Formula (14)) manufactured by BASF SE was used.

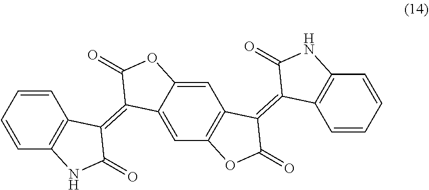 [SMILES: O=C1Nc2ccccc2/C1=C1\C(=O)Oc2cc3c(cc21)OC(=O)/C3=C1/C(=O)Nc2ccccc21]

### Dispersant A

A methacrylic AB block copolymer consisting of an A block having a nitrogen atom-containing functional group and a B block having a solvophilic group was used. The dispersant A has a repeating unit represented by Formula (1a), a repeating unit represented by Formula (2a), a repeating unit represented by Formula (3a), a repeating unit represented by Formula (4a), and a repeating unit represented by Formula (5a). The amine value is 120 mgKOH/g and the acid value is less than 1 mgKOH/g.

The content proportions of the repeating units represented by Formulae (1a), (2a), (3a), (4a), and (5a) in all repeating units of the dispersant A are each less than 1% by mole, 34.5% by mole, 6.9% by mole, 13.8% by mole, and 6.9% by mole.

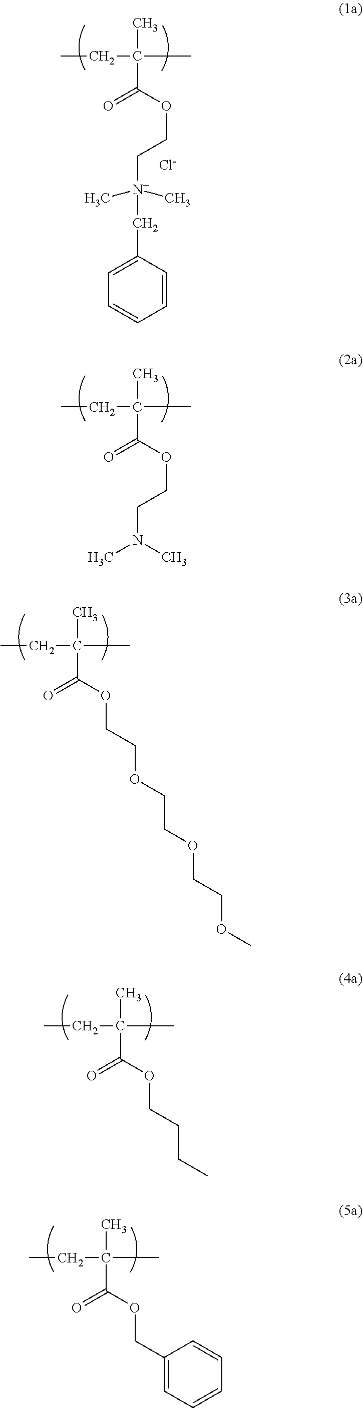

### Dispersant B

An acrylic A-B block copolymer consisting of an A block having a quaternary ammonium base and a tertiary amino group in a side chain and a B block not having a quaternary ammonium base and a tertiary amino group in a side chain was used. The amine value is 70 mgKOH/g and the acid value is 1 mgKOH/g or less. The A block of the dispersant B includes the repeating units of Formulae (1a) and (2a), and the B block includes the repeating unit of Formula (3a). The content proportions of the repeating units of Formulae (1a), (2a), and (3a) in all repeating units of the dispersant B are each 11.1% by mole, 22.2% by mole, and 6.7% by mole.

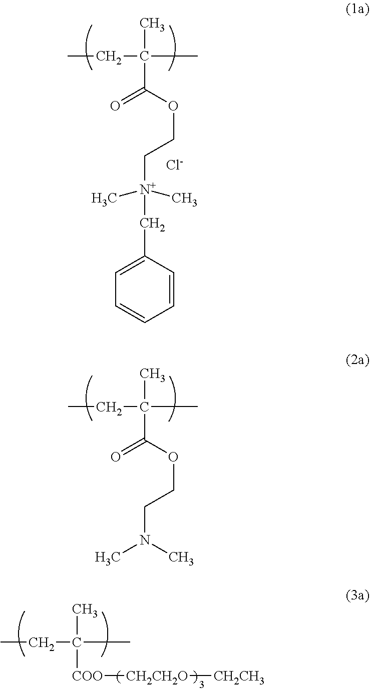

### Dispersion Resin A

A separable flask equipped with a cooling tube as a reaction tank was prepared, 400 parts by mass of propylene glycol monomethyl ether acetate was charged therein, and after replacing with nitrogen, the reaction tank was heated with an oil bath while stirring to raise the temperature to 90° C.

On the other hand, 30 parts by mass of dimethyl-2,2′-[oxybis(methylene)]bis-2-propenoate, 60 parts by mass of methacrylic acid, 110 parts by mass of cyclohexyl methacrylate, 5.2 parts by mass of t-butylperoxy-2-ethylhexanoate, and 40 parts by mass of propylene glycol monomethyl ether acetate were charged into a monomer tank, and 5.2 parts by mass of n-dodecyl mercaptan and 27 parts by mass of propylene glycol monomethyl ether acetate were charged into a chain transfer agent tank. When the temperature of the reaction tank was stabilized at 90° C., dropwise addition of the contents from the monomer tank and the chain transfer agent tank was initiated to initiate polymerization. The dropwise addition was performed over 135 minutes while maintaining the temperature at 90° C., and after 60 minutes from completion of the dropwise addition, the reaction tank was set to 110° C. by starting raising the temperature.

After maintaining the temperature at 110° C. for 3 hours, a gas inlet tube was attached to a separable flask and bubbling of a mixed gas of oxygen/nitrogen=5/95 (v/v) was started. Next, 39.6 parts by mass of glycidyl methacrylate, 0.4 parts by mass of 2,2′-methylenebis(4-methyl-6-t-butylphenol), and 0.8 parts by mass of triethylamine were charged into the reaction tank, and the mixture was reacted at 110° C. for 9 hours as it was.

The mixture was cooled to room temperature to obtain a dispersion resin A having a polystyrene-equivalent weight-average molecular weight Mw, as measured by gel permeation chromatography (GPC), of 9,000, an acid value of 101 mgKOH/g, and a double bond equivalent of 550 g/mol.

### Dispersion Resin B

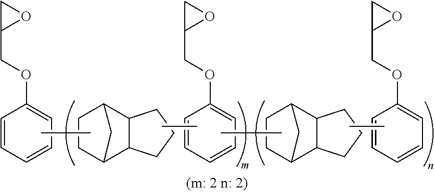

155 parts by mass of the epoxy compound represented by the structural formula (EPICLON HP7200HH manufactured by DIC Corporation, polyglycidyl ether of a dicyclopentadiene/phenol polymer, a weight-average molecular weight of 1,000, and an epoxy equivalent of 270), 41 parts by mass of acrylic acid, 0.1 parts by mass of p-methoxyphenol, 2.5 parts by mass of triphenylphosphine, and 130 parts by mass of propylene glycol monomethyl ether acetate were charged into a reaction vessel, and the mixture was heated and stirred at 100° C. until the acid value reached 3.0 mgKOH/g or less. It took 9 hours for the acid value to reach a target (acid value: 2.9 mgKOH/g). Next, 74 parts by mass of tetrahydrophthalic anhydride was further added thereto and reacted at 120° C. for 4 hours to obtain a dispersion resin B having an acid value of 98 mgKOH/g and a weight-average molecular weight (Mw) of 3,500.

### Alkali-Soluble Resin A

145 parts by mass of propylene glycol monomethyl ether acetate was stirred while replacing with nitrogen, and the temperature was raised to 120° C. 10.4 parts by mass of styrene, 85.2 parts by mass of glycidyl methacrylate, and 66.0 parts by mass of monomethacrylate (FA-513M manufactured by Hitachi Chemical Co., Ltd.) having a tricyclodecane skeleton were added dropwise thereto, and a mixed solution of 8.47 parts by mass of 2,2′-azobis-2-methylbutyronitrile was added dropwise to the mixture over 3 hours. Stirring was further continued at 90° C. for 2 hours. Next, the inside of the reaction vessel was changed to air replacement, 15.1 parts by mass of acrylic acid, 0.3 parts by mass of trisdimethylaminomethylphenol, and 0.06 parts by mass of hydroquinone were put thereinto, and the reaction was continued at 120° C. for 6 hours. Thereafter, 59.3 parts by mass of tetrahydrophthalic anhydride (THPA) and 1.4 parts by mass of triethylamine were added thereto, and the mixture was reacted at 120° C. for 3.5 hours. The polystyrene-equivalent weight-average molecular weight Mw, as measured by GPC, of the alkali-soluble resin obtained in this manner, was approximately 9,000, the acid value was 80 mgKOH/g, and the double bond equivalent was 480 g/mol. Propylene glycol monomethyl ether acetate was added to this resin solution so that the solid content reached 40% by mass, and the mixture was used as the alkali-soluble resin A.

### Alkali-Soluble Resin B

145 parts by mass of propylene glycol monomethyl ether acetate was stirred while replacing with nitrogen, and the temperature was raised to 120° C. 10 parts by mass of styrene, 85.2 parts by mass of glycidyl methacrylate and 66 parts by mass of monomethacrylate (FA-513M manufactured by Hitachi Chemical Co., Ltd.) having a tricyclodecane skeleton were added dropwise thereto, and 8.47 parts by mass of 2,2′-azobis-2-methylbutyronitrile was added dropwise to the mixture over 3 hours. Stirring was further continued at 90° C. for 2 hours. Next, the inside of the reaction vessel was changed to air replacement, 43.2 parts by mass of acrylic acid, 0.7 parts by mass of trisdimethylaminomethylphenol, and 0.12 parts by mass of hydroquinone were put thereto, and the reaction was continued at 100° C. for 12 hours. Thereafter, 56.2 parts by mass of tetrahydrophthalic anhydride (THPA) and 0.7 parts by mass of triethylamine were added thereto, and the reaction was performed at 100° C. for 3.5 hours. The weight-average molecular weight (Mw) of the alkali-soluble resin B obtained in this manner was approximately 8,400, the acid value was 80 mgKOH/g, and the double bond equivalent was 480 g/mol.

### Near-Infrared Absorbing Colorant A

A near-infrared absorbing colorant A having the following chemical structure, synthesized based on Kousik Kundu, Sarah F. Knight, Seungjun Lee, W. Robert Taylor, and Niren Murthy Angew. Chem. Int. Ed. 2010, 49, 6134-6138 (Reference 1), was used.

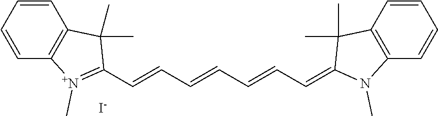 [SMILES: CN1/C(=C/C=C/C=C/C=C/C2=[N+](C)c3ccccc3C2(C)C)C(C)(C)c2ccccc21 ; [I-]]

### Near-Infrared Absorbing Colorant B

A near-infrared absorbing colorant B having the following chemical structure, synthesized based on I. G. Davidenko, Yu. L. Slominskii, A. D. Kachkovskii, and A. I. Tolmachev, Ukrainskii Khimicheskii Zhurnal (Russian Edition) 2008, 74 (3-4), 105-113 (Reference 2), was used.

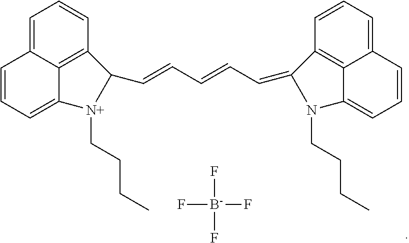 [SMILES: CCCCn1/c(=C/C=C/C=C/C2c3cccc4cccc(c34)[NH+]2CCCC)c2cccc3cccc1c32 ; F[B-](F)(F)F]

### Near-Infrared Absorbing Colorant C

A near-infrared absorbing colorant C having the following chemical structure, synthesized based on Yukinori Nagao, Toshifumi Sakai, Kozo Kozawa, Toshiyuki Urano, Dyes and Pigments 2006, 73 (3), 344-352 (Reference 3), was used.

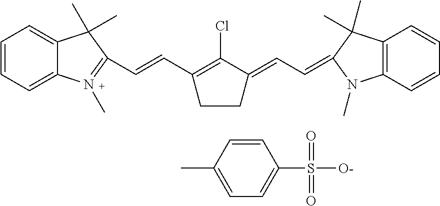

### Near-Infrared Absorbing Colorant D

A near-infrared absorbing colorant D having the following chemical structure, synthesized based on Hui Zhang, Gaetan Wicht, Christina Gretener, Matthias Nagel, Frank Nuesch, Yaroslav Romanyuk, Jean-Nicolas Tisserant, Roland Hany, Solar Energy Materials & Solar Cells 2013 118, 157-164 (Reference 4), was used.

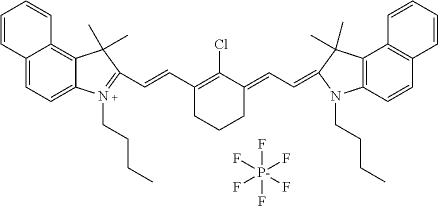

### Preparation of Red Colorant Dispersion A

As described in Table 1, 12.6 parts by mass of the red colorant A, 3.2 parts by mass in terms of a solid content of the dispersant A as a dispersant, 4.2 parts by mass in terms of a solid content of the dispersion resin A as a dispersion resin, 76.0 parts by mass of propylene glycol monomethyl ether acetate (PGMEA) (including a solvent derived from the dispersant and the dispersion resin) as a solvent, 4.0 parts by mass of propylene glycol monomethyl ether (PGME), and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a red colorant dispersion A.

### Preparation of Red Colorant Dispersion B

As described in Table 1, 15.0 parts by mass of C. I. Pigment Red 177 as the red colorant B, 2.0 parts by mass in terms of a solid content of the dispersant A as a dispersant, 6.0 parts by mass in terms of a solid content of the dispersion resin A as a dispersion resin, 77.0 parts by mass of propylene glycol monomethyl ether acetate (PGMEA) (including those derived from the dispersant and the dispersion resin) as a solvent, and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a red colorant dispersion B.

### Preparation of Yellow Colorant Dispersion A

As described in Table 1, 11.4 parts by mass of E4GN-GT manufactured by LANXESS K. K. as a yellow colorant A, 2.9 parts by mass in terms of a solid content of the dispersant A as a dispersant, 5.7 parts by mass in terms of a solid content of the dispersion resin A as a dispersion resin, 80.0 parts by mass of propylene glycol monomethyl ether acetate (PGMEA) (including those derived from the dispersant and the dispersion resin) as a solvent, and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a yellow colorant dispersion A.

### Preparation of Yellow Colorant Dispersion B

As described in Table 1, 11.4 parts by mass of C. I. Pigment Yellow 138 as a yellow colorant B, 2.9 parts by mass in terms of a solid content of the dispersant A as a dispersant, 5.7 parts by mass in terms of a solid content of the dispersion resin A as a dispersion resin, 76.0 parts by mass of propylene glycol monomethyl ether acetate (PGMEA) (including a solvent derived from the dispersant and the dispersion resin) as a solvent, 4.0 parts by mass of propylene glycol monomethyl ether (PGME), and 225 parts by mass of zirconia beads with a diameter of 0.5 mm were charged into a stainless steel container, and the mixture was subjected to a dispersing treatment for 6 hours by a paint shaker. After the completion of dispersion, the beads and the dispersion were separated by a filter to prepare a yellow colorant dispersion B.

### Preparation of Green Colorant Dispersion A

As described in Table 1, 9.9 parts by mass of the green colorant A, 0.1 parts by mass in terms of a solid content of the dispersant A, 72.0 parts by mass of propylene glycol monomethyl ether acetate (PGMEA) (including a solvent derived from the dispersant A) as a solvent, 18.0 parts by mass of propylene glycol monomethyl ether (PGME), and 225 parts by mass of zirconia beads having a diameter of 0.5 mm were charged into a stainless steel container, and the mixture was subjected to a dispersing treatment for 6 hours by a paint shaker. After the completion of dispersion, the beads and the dispersion were separated by a filter to prepare a green colorant dispersion A.

### Preparation of Black Colorant Dispersion A

As described in Table 1, 5.6 parts by mass of the black colorant A, 1.1 parts by mass in terms of a solid content of the dispersant B as a dispersant, 2.8 parts by mass in terms of a solid content of the dispersion resin B as a dispersion resin, 72.4 parts by mass of propylene glycol monomethyl ether acetate (PGMEA) (including a solvent derived from the dispersant A) as a solvent, 18.1 parts by mass of 3-methoxybutanol (MB), and 225 parts by mass of zirconia beads having a diameter of 0.5 mm were charged into a stainless steel container, and the mixture was subjected to a dispersing treatment for 6 hours by a paint shaker. After the completion of dispersion, the beads and the dispersion were separated by a filter to prepare a black colorant dispersion A.

TABLE 1

| | | Red | Red | Yellow | Yellow | Green | Black |
|---|---|---|---|---|---|---|---|
| | | colorant | colorant | colorant | colorant | colorant | colorant |
| | | dispersion A | dispersion B | dispersion A | dispersion B | dispersion A | dispersion A |
| Blend | Red colorant A | 12.6 | — | — | — | — | — |
| proportion | Red colorant B | — | 15.0 | — | — | — | — |
| | Yellow colorant A | — | — | 11.4 | — | — | — |
| | Yellow colorant B | — | — | — | 11.4 | — | — |
| | Green colorant A | — | — | — | — | 9.9 | — |
| | Black colorant A | — | — | — | — | — | 5.6 |
| | Dispersant A | 3.2 | 2.0 | 2.9 | 2.9 | 0.1 | — |
| | Dispersant B | — | — | — | — | — | 1.1 |
| | Dispersion resin A | 4.2 | 6.0 | 5.7 | 5.7 | — | — |
| | Dispersion resin B | — | — | — | — | — | 2.8 |
| | PGMEA | 76.0 | 77.0 | 80.0 | 76.0 | 72.0 | 72.4 |
| | PGME | 4.0 | — | — | 4.0 | 18.0 | — |
| | MB | — | — | — | — | — | 18.1 |

Furthermore, the unit of each numerical value in Table 1 is part by mass.

### Photopolymerizable Monomer A

A mixture of dipentaerythritol hexaacrylate and dipentaerythritol pentaacrylate (A-9550 manufactured by Shin-Nakamura Chemical Co., Ltd.).

### Photopolymerizable Monomer B

Trimethylolpropane triacrylate (Light Acrylate TMP-A manufactured by Kyoeisha Chemical Co., Ltd.).

### Photopolymerizable Monomer C

A monomer having a urethane skeleton in which hexamethylene diisocyanate is bonded to dipentaerythritol pentaacrylate (DPHA-40H manufactured by Nippon Kayaku Co., Ltd.).

### Photopolymerization Initiator A

An oxime ester-based compound having the following chemical structure.

(Methyl 4-acetoxyimino-5-[9-ethyl-6-(2-methylbenzoyl)-9H-carbazol-3-yl]-5-oxopentanoate).

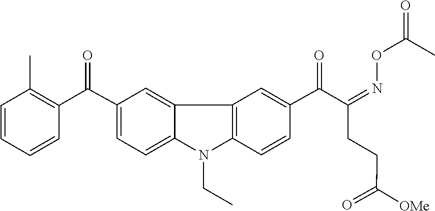 [SMILES: CCn1c2ccc(C(=O)/C(CCC(=O)OC)=N\OC(C)=O)cc2c2cc(C(=O)c3ccccc3C)ccc21]

### Photopolymerization Initiator B

An oxime ester-based compound having the following chemical structure.

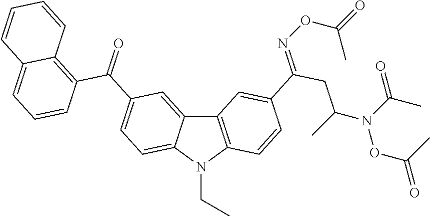 [SMILES: CCn1c2ccc(C(=O)c3cccc4ccccc34)cc2c2cc(/C(CC(C)N(OC(C)=O)C(C)=O)=N/OC(C)=O)ccc21]

### Surfactant A

MEGAFACE F-554 (manufactured by DIC Corporation).

### Additive A

BYK-330 (manufactured by BYK Chemie GmbH).

### Preparation of Colored Resin Composition

Each component shown in Table 2 was mixed at a solid content ratio shown in Table 2 to prepare a colored resin composition for forming each of the primary color filters of RGB, the first infrared color filter, and the second infrared color filter.

Furthermore, the unit of each numerical value in Table 2 is part by mass.

TABLE 2

| | | | | First | Second |
|---|---|---|---|---|---|
| | | | | infra- | infra- |
| | | | | red | red |
| | R | G | B | rays | rays |
| Red colorant dispersion A | 33.5 | — | — | — | — |
| Red colorant dispersion B | 12.7 | — | — | — | — |
| Yellow colorant dispersion A | 14.3 | 4.1 | — | — | — |
| Yellow colorant dispersion B | — | 45.5 | — | — | — |
| Green colorant dispersion A | — | 14.3 | — | — | — |
| Blue colorant A | — | — | 17.4 | — | — |
| Black colorant dispersion A | — | — | — | 88.1 | 91.2 |
| Near-infrared absorbing colorant A | — | 0.5 | 0.5 | — | 0.5 |
| Near-infrared absorbing colorant B | 0.9 | 0.9 | 0.9 | — | — |
| Near-infrared absorbing colorant C | 1.9 | — | — | — | — |
| Near-infrared absorbing colorant D | — | — | — | 3.8 | — |
| Alkali-soluble resin A | 22.2 | 16.8 | 57.5 | — | — |
| Alkali-soluble resin B | — | — | — | 5.3 | 5.5 |
| Photopolymerizable monomer A | 12.2 | 15.5 | 21.3 | — | — |
| Photopolymerizable monomer B | — | — | — | 1.0 | 1.1 |
| Photopolymerizable monomer C | — | — | — | 1.0 | 1.1 |
| Photopolymerization initiator A | 2.3 | 2.4 | 2.4 | — | — |
| Photopolymerization initiator B | — | — | — | 0.7 | 0.7 |
| Surfactant A | 0.1 | 0.1 | 0.1 | — | — |
| Additive A | — | — | — | 0.01 | 0.01 |

### Measurement of Color Characteristics

The obtained colored resin composition was applied onto a glass substrate (AN100 manufactured by AGC Inc.) with a size of 50 mm square and a thickness of 0.7 mm by a spin coating method, dried under reduced pressure, and then pre-baked on a hot plate at 90° C. for 90 seconds. Next, an entire-surface exposure treatment was performed at an exposure amount of 40 mJ/cm² and an illuminance of 30 mW/cm², using a 2-kW high-pressure mercury lamp. Thereafter, a development treatment was performed at a developer temperature of 23° C. for 60 seconds, using a 0.04% by mass aqueous solution of potassium hydroxide. Next, a spray water rinsing treatment was performed at a water pressure of 1 kg/cm² for 10 seconds. Thereafter, a thermosetting treatment was performed at 230° C. for 20 minutes in a clean oven to create a colored substrate. Each of colored substrates, each having color filters of five colors, was created.

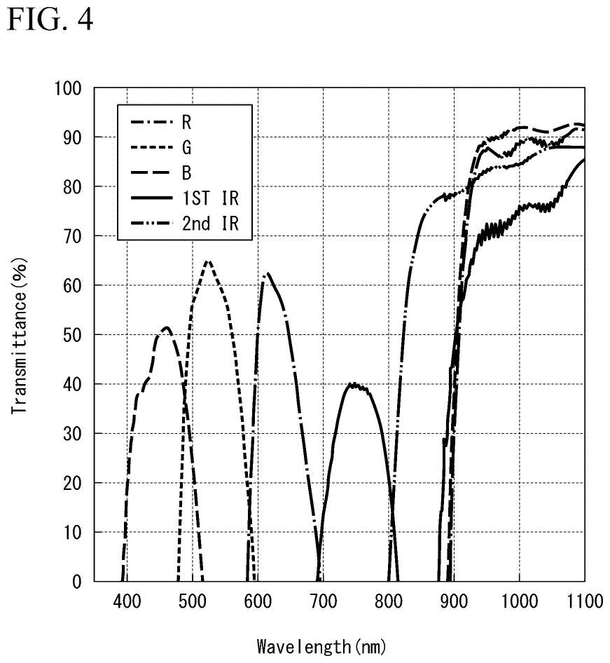

The transmission spectrum of the obtained colored substrate was measured with a spectrophotometer U-3310 manufactured by Hitachi, Ltd. The results thereof are shown in FIG. 4.

As shown in FIG. 4, it was found that according to the created color filters, the visible region and the infrared region can be spectrally split into five colors and the maximum transmittances in a wavelength range of 400 to 900 nm are all 35% or more.

### INDUSTRIAL AVAILABILITY

The solid-state imaging device of the present invention is provided with color filters that can spectrally split infrared rays included in incident light into two or more colors, and is useful as a device that enables high-level imaging to be performed.

### REFERENCE SIGNS LIST

1 solid-state imaging device
2 infrared cut filter
3 color filter
4 photoelectric conversion device
5 semiconductor substrate
31 infrared shielding and visible transmitting filter
31a blue color filter
31b green color filter
31c red color filter
32 visible shielding and infrared transmitting filter
32a first infrared color filter
32b second infrared color filter

What is claimed is:

1. A structure comprising:
a plurality of color filters positioned on a support,
wherein the color filters comprise a first infrared color filter and a second infrared color filter, and
when a near-infrared region is divided into two parts, a short wavelength side is defined as a specific wavelength band 1, and a long wavelength side is defined as a specific wavelength band 2,
the first infrared color filter shields light in a visible region, transmits at least a part of light in the specific wavelength band 1, and shields light in the specific wavelength band 2, and
the second infrared color filter shields light in the visible region, shields light in the specific wavelength band 1, and transmits at least a part of light in the specific wavelength band 2.

2. The structure according to claim 1,
wherein a wavelength range of 700 to 900 nm is divided into two parts, a short wavelength side is defined as the specific wavelength band 1, and a long wavelength side is defined as the specific wavelength band 2.

3. The structure according to claim 2,
wherein the specific wavelength band 1 is in a wavelength range of 700 to 800 nm and the specific wavelength band 2 is in a wavelength range of 800 to 900 nm.

4. The structure according to claim 1,
wherein the color filters comprise a plurality of infrared shielding and visible transmitting filters that shield light in the near-infrared region and transmit at least a part of light in the visible region.

5. The structure according to claim 1,
wherein the first infrared color filter has an average transmittance in the specific wavelength band 1 of 30% or more and an average transmittance in the specific wavelength band 2 of 0.1% or less.

6. The structure according to claim 1,
wherein the second infrared color filter has an average transmittance in the specific wavelength band 1 of 0.1% or less and an average transmittance in the specific wavelength band 2 of 30% or more.

7. The structure according to claim 3,
wherein the first infrared color filter has an average transmittance in a wavelength range of 700 to 800 nm of 30% or more and an average transmittance in a wavelength range of 800 to 900 nm of 0.1% or less.

8. The structure according to claim 3,
wherein the second infrared color filter has an average transmittance in a wavelength range of 700 to 800 nm of 0.1% or less and an average transmittance in a wavelength range of 800 to 900 nm of 30% or more.

9. The structure according to claim 1,
wherein the first infrared color filter and the second infrared color filter are films obtained from a photosensitive resist containing a colorant.

10. The structure according to claim 1
wherein the color filters have a maximum transmittance of 35% or more in a wavelength range of 400 to 900 nm.

11. The structure according to claim 1,
wherein the color filters constitute a color filter array disposed in a planar shape.

12. The structure according to claim 4,
wherein the infrared shielding and visible transmitting filters include a green color filter, and
a proportion of an area occupied by the green color filter with respect to an area occupied by the infrared shielding and visible transmitting filters is highest.

13. The structure according to claim 4,
wherein the infrared shielding and visible transmitting filters include a blue color filter that transmits light at a wavelength of 400 to 500 nm, a green color filter that transmits light at a wavelength of 500 to 600 nm, and a red color filter that transmits light at a wavelength of 600 to 700 nm.

14. The structure according to claim 4,
wherein the infrared shielding and visible transmitting filters have an average transmittance in a wavelength range of 700 to 900 nm of 0.1 or less.

15. A solid-state imaging device comprising:
the structure according to claim 1.

16. The solid-state imaging device according to claim 15, further comprising:
an infrared cut filter that shields light at a wavelength of more than 900 nm;
a photoelectric conversion device having a sensitivity to visible light and light at a wavelength of 700 to 900 nm;
a readout circuit that reads out an electrical signal photoelectrically converted by the photoelectric conversion device; and
a signal processing section that performs signal processing on the electrical signal read out by the readout circuit.

17. The solid-state imaging device according to claim 16,
wherein the infrared cut filter is a laminated film in which a plurality of films including two or more kinds of substances with different optical refractive indices are laminated.

18. The solid-state imaging device according to claim 16,
wherein the photoelectric conversion device is a photodiode using silicon.
